(19) United States
(12) Patent Application Publication
(10) Pub. No.: US 2024/0324304 A1
(43) Pub. Date: Sep. 26, 2024

(54) DISPLAY APPARATUS AND METHOD OF MANUFACTURING THE SAME

(71) Applicant: Samsung Display Co., Ltd., Yongin-si (KR)

(72) Inventors: Youngrok Kim, Yongin-si (KR); Woojin Cho, Yongin-si (KR); Joonhwa Bae, Yongin-si (KR); Sukyeong Shin, Yongin-si (KR); Heesung Yang, Yongin-si (KR)

(73) Assignee: Samsung Display Co., Ltd., Yongin-si (KR)

(21) Appl. No.: 18/504,162

(22) Filed: Nov. 8, 2023

(30) Foreign Application Priority Data
Mar. 24, 2023 (KR) 10-2023-0039046
Apr. 12, 2023 (KR) 10-2023-0048432

(51) Int. Cl. H10K 59/122; H10K 59/12

(52) U.S. Cl. CPC H10K 59/122; H10K 59/1201

(57) ABSTRACT

A display apparatus includes an organic insulating layer located on a substrate, and including a first opening, a second opening, and a third opening, a first pixel electrode and a second pixel electrode located on the organic insulating layer and respectively disposed in the first opening and the second opening, a pixel-defining film located on the organic insulating layer and protruding toward the third opening beyond the organic insulating layer, a first intermediate layer and a second intermediate layer respectively located on the first pixel electrode and the second pixel electrode, and a counter electrode located on the first intermediate layer and the second intermediate layer.

### CROSS-REFERENCE TO RELATED APPLICATION

This application is based on and claims priority to and benefits of Korean Patent Application Nos. 10-2023-0039046 and 10-2023-0048432 under 35 U.S.C. § 119, respectively filed on Mar. 24, 2023 and Apr. 12, 2023, in the Korean Intellectual Property Office (KIPO), the disclosures of which are incorporated herein by reference in their entirety.

### BACKGROUND

### 1. Technical Field

One or more embodiments relate to a display apparatus and a method of manufacturing the same.

### 2. Description of the Related Art

Display apparatuses are apparatuses for providing visual information such as images or videos to users. With the development of various electronic devices such as computers and large TVs, various types of display apparatuses applicable to electronic devices have been developed. Recently, mobility-based electronic devices have been widely used, and tablet personal computers (PCs), in addition to small electronic devices such as mobile phones, have been widely used as mobile electronic devices.

A display apparatus includes a display area and a non-display area, and light-emitting devices are located in the display area. The display apparatus may provide an image through light emitted by the light-emitting devices. Each of the light-emitting devices may include a pixel electrode and a counter electrode.

### SUMMARY

One or more embodiments include a display apparatus having improved reliability and resolution and a method of manufacturing the display apparatus. However, the embodiments are examples, and do not limit the scope of the disclosure.

Additional aspects will be set forth in part in the description which follows and, in part, will be apparent from the description, or may be learned by practice of the presented embodiments.

According to one or more embodiments, a display apparatus includes an organic insulating layer located on a substrate, and including a first opening, a second opening, and a third opening, a first pixel electrode and a second pixel electrode each located on the organic insulating layer and respectively disposed in the first opening and the second opening, a pixel-defining film located on the organic insulating layer and protruding toward the third opening beyond the organic insulating layer, a first intermediate layer and a second intermediate layer respectively located on the first pixel electrode and the second pixel electrode, and a counter electrode located on the first intermediate layer and the second intermediate layer.

The pixel-defining film may have an undercut shape in the third opening of the organic insulating layer.

The pixel-defining film may include openings overlapping at least parts of the first opening, the second opening, and the third opening.

The third opening of the organic insulating layer may be located between the first opening and the second opening.

The display apparatus may further include a dummy intermediate layer located in the third opening of the organic insulating layer.

A first organic light-emitting diode may include the first pixel electrode, the first intermediate layer, and the counter electrode.

A second organic light-emitting diode may include the second pixel electrode, the second intermediate layer, and the counter electrode.

A top surface of the first pixel electrode and a top surface of the organic insulating layer may be located on a same plane.

A top surface of the second pixel electrode and a top surface of the organic insulating layer may be located on a same plane.

According to one or more embodiments, a method of manufacturing a display apparatus includes forming, on a substrate, an organic insulating layer including a first opening, a second opening, and a third opening, respectively forming a first pixel electrode and a second pixel electrode in the first opening and the second opening of the organic insulating layer, forming, on the organic insulating layer, a pixel-defining film protruding toward the third opening beyond the organic insulating layer, respectively forming a first intermediate layer and a second intermediate layer on the first pixel electrode and the second pixel electrode, and locating a counter electrode on the first intermediate layer and the second intermediate layer.

The pixel-defining film may be provided in an undercut shape in the third opening of the organic insulating layer.

The pixel-defining film may include openings overlapping at least parts of the first opening, the second opening, and the third opening of the organic insulating layer.

The method may further include forming a dummy intermediate layer in the third opening of the organic insulating layer.

A first organic light-emitting diode may include the first pixel electrode, the first intermediate layer, and the counter electrode, and a second organic light-emitting diode may include the second pixel electrode, the second intermediate layer, and the counter electrode.

The method may further include locating an organic insulating layer forming material on the substrate, locating a first photoresist on at least a part of the organic insulating layer forming material, forming the organic insulating layer including the first opening, the second opening, and the third opening, by etching a portion of the organic insulating layer forming material on which the first photoresist is not located, and removing the first photoresist.

The method may further include locating a pixel electrode forming material on the organic insulating layer, and forming the first pixel electrode and the second pixel electrode, by planarizing the pixel electrode forming material such that a top surface of the pixel electrode forming material and a top surface of the organic insulating layer are located on a same plane.

The method may further include locating a pixel-defining film forming material on the organic insulating layer, locating a second photoresist on at least a part of the pixel-defining film forming material, forming the pixel-defining film including the openings overlapping at least parts of the first opening and the second opening, by etching a portion of the pixel-defining film forming material on which the second photoresist is not located, and removing the second photoresist.

The method may further include locating a third photoresist on at least a part of the pixel-defining film, and forming an opening overlapping at least a part of the third opening in the pixel-defining film by etching a portion of the pixel-defining film on which the third photoresist is not located.

The method may further include etching and removing the pixel electrode forming material located in the third opening of the organic insulating layer.

The method may further include forming, by locating an intermediate layer forming material on the substrate, the first intermediate layer located on the first pixel electrode, the second intermediate layer located on the second pixel electrode, and the dummy intermediate layer located in the third opening.

### BRIEF DESCRIPTION OF THE DRAWINGS

The above and other aspects, features, and advantages of embodiments will be more apparent from the following description taken in conjunction with the accompanying drawings, in which:

FIG. 1 is a perspective view schematically illustrating a display apparatus, according to an embodiment;

FIG. 2 is a diagram of an equivalent circuit schematically illustrating a pixel included in the display apparatus of FIG. 1;

FIG. 3 is a cross-sectional view schematically illustrating a display apparatus, according to an embodiment;

FIG. 4 is a cross-sectional view schematically illustrating a display apparatus; and

FIGS. 5 to 19 are cross-sectional views schematically illustrating a method of manufacturing a display apparatus.

### DETAILED DESCRIPTION OF THE EMBODIMENTS

Reference will now be made in detail to embodiments, examples of which are illustrated in the accompanying drawings, wherein like reference numerals and/or reference characters refer to like elements throughout. In this regard, the embodiments may have different forms and should not be construed as being limited to the descriptions set forth herein. Accordingly, the embodiments are merely described below, by referring to the figures, to explain aspects of the description.

The term “and/or” includes all combinations of one or more of which associated configurations may define. For example, “A and/or B” may be understood to mean “A, B, or A and B.”

For the purposes of this disclosure, the phrase “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z.

As the disclosure allows for various changes and numerous embodiments, certain embodiments will be illustrated in the drawings and described in the detailed description. Effects and features of the disclosure, and methods for achieving them will be clarified with reference to embodiments described below in detail with reference to the drawings. However, the disclosure is not limited to the following embodiments and may be embodied in various forms.

Hereinafter, embodiments will be described in detail with reference to the accompanying drawings, wherein the same or corresponding elements are denoted by the same reference numerals throughout and a repeated description thereof is omitted.

Although the terms “first,” “second,” etc. may be used to describe various elements, these elements should not be limited by these terms. These terms are only used to distinguish one element from another.

As used herein, the singular forms “a,” “an,” and “the” are intended to include the plural forms as well, unless the context clearly indicates otherwise.

It will be understood that the terms “include,” “comprise,” “have,” and their variations are intended to indicate the existence of the features or elements described in the specification, and are not intended to preclude the possibility that one or more other features or elements may exist or may be added.

It will be further understood that, when a layer, region, or component is referred to as being “on” another layer, region, or component, it may be directly on the other layer, region, or component, or may be indirectly on the other layer, region, or component with intervening layers, regions, or components therebetween.

Sizes of components in the drawings may be exaggerated or contracted for convenience of explanation. For example, because sizes and thicknesses of elements in the drawings are arbitrarily illustrated for convenience of explanation, the disclosure is not limited thereto.

When a certain embodiment may be implemented differently, a specific process order may be different from the described order. For example, two consecutively described processes may be performed substantially at the same time or may be performed in an order opposite to the described order.

It will be understood that when a layer, an area, or an element is referred to as being “connected” to another layer, area, or element, it may be “directly connected” to the other layer, area, or element and/or may be “indirectly connected” to the other layer, area, or element with other layers, areas, or elements interposed therebetween. For example, when a layer, an area, or a component is referred to as being “electrically connected,” it may be directly electrically connected, and/or may be indirectly electrically connected with intervening layers, areas, or components therebetween.

The x-axis, the y-axis and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

The term “about” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

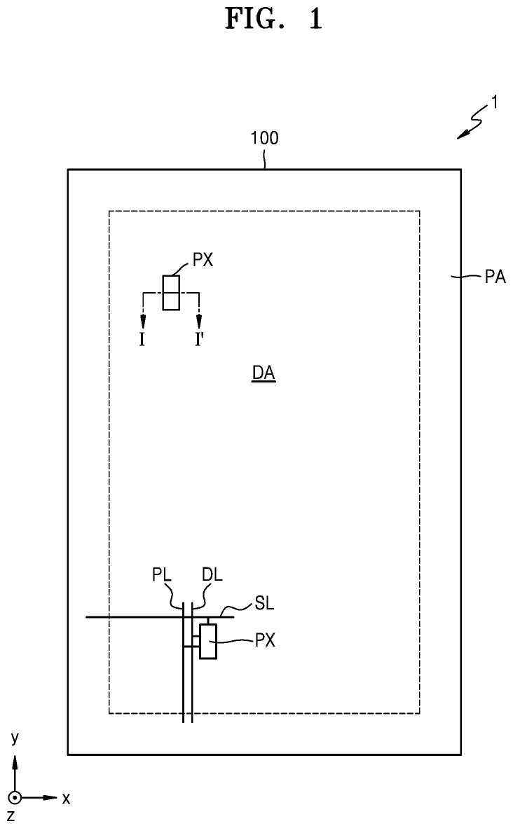

FIG. 1 is a perspective view schematically illustrating a display apparatus, according to an embodiment.

Referring to FIG. 1, a display apparatus 1 according to an embodiment may be any of various apparatuses such as a smartphone, a tablet, a laptop, a television, or an advertisement board. The display apparatus 1 according to an embodiment may include thin-film transistors (or transistors) and a capacitor, and the thin-film transistors and the capacitor may be implemented by conductive layers and insulating layers.

The display apparatus 1 may include a display area DA and a peripheral area PA located outside the display area DA. In FIG. 1, the display area DA has a rectangular shape. However, the disclosure is not limited thereto. The display area DA may have any of various shapes such as a circular shape, an elliptical shape, a polygonal shape, or a specific shape.

The display area DA may be a portion where an image is displayed, and pixels PX may be located in the display area DA. Each pixel PX may include a display device such as an organic light-emitting diode. Each pixel PX may emit, for example, red light, green light, or blue light. The pixel PX may be connected to a pixel circuit including a thin-film transistor TFT and a storage capacitor. The pixel circuit may be connected to a scan line SL that transmits a scan signal, a data line DL that intersects the scan line SL and transmits a data signal, and a driving voltage line PL that supplies a driving voltage. The scan line SL may extend in an x direction (hereinafter, referred to as a second direction), and the data line DL and the driving voltage line PL may extend in a y direction (hereinafter, referred to as a first direction).

The pixel PX may emit light having a luminance corresponding to an electrical signal from the pixel circuit that is electrically connected. The display area DA may display a certain image through light emitted from the pixel PX. For reference, the pixel PX may be defined as an emission area that emits light of, e.g., any one color from among red, green, and blue as described above.

The peripheral area PA may be a portion where the pixel PX is not located and an image is not displayed. In the peripheral area PA, a power supply wiring for driving the pixel PX may be located. Also, in the peripheral area PA, pads may be located, and an integrated circuit device such as a driver IC or a printed circuit board including a driving circuit unit may be electrically connected to the pads.

For reference, because the display panel 10 may include a substrate 100, the substrate 100 may include the display area DA and the peripheral area PA. The substrate 100 will be described below in detail.

Also, transistors may be located in the display area DA. In the transistors, a first terminal of the transistor may be a source electrode or a drain electrode, and a second terminal may be an electrode different from the first terminal, according to a type (N-type or P-type) and/or an operating condition of the transistor. For example, in case that the first terminal is a source electrode, the second terminal may be a drain electrode.

The transistors may include a driving transistor, a data write transistor, a compensation transistor, an initialization transistor, and/or an emission control transistor. The driving transistor may be connected between the driving voltage line PL and an organic light-emitting diode OLED, and the data write transistor may be connected to the data line DL and the driving transistor and may perform a switching operation of transmitting a data signal transmitted through the data line DL.

The compensation transistor may be turned on according to a scan signal received through the scan line SL to connect the driving transistor to the organic light-emitting diode OLED and compensate for a threshold voltage of the driving transistor.

The initialization transistor may be turned on according to a scan signal received through the scan line SL to transmit an initialization voltage to a gate electrode of the driving transistor and initialize the gate electrode of the driving transistor. The scan line connected to the initialization transistor may be a separate scan line different from the scan line connected to the compensation transistor.

The emission control transistor may be turned on according to an emission control signal received through an emission control line, and as a result, driving current may flow through the organic light-emitting diode OLED.

The organic light-emitting diode OLED may include a pixel electrode (anode) and a counter electrode (cathode), and the counter electrode 160 may receive a second power supply voltage ELVSS. The organic light-emitting diode OLED may receive the driving current from the driving transistor to emit light and display an image.

Hereinafter, although an organic light-emitting display apparatus is described as the display apparatus 1 according to an embodiment, the display apparatus 1 of the disclosure is not limited thereto. In another embodiment, the display apparatus 1 of the disclosure may be a display apparatus such as an inorganic light-emitting display apparatus (or an inorganic electroluminescent (EL) display apparatus) or a quantum dot light-emitting display apparatus.

For example, an emission layer of a display device included in the display apparatus may include an organic material or an inorganic material. Also, the display apparatus may include an emission layer, and quantum dots located in a path of light emitted from the emission layer.

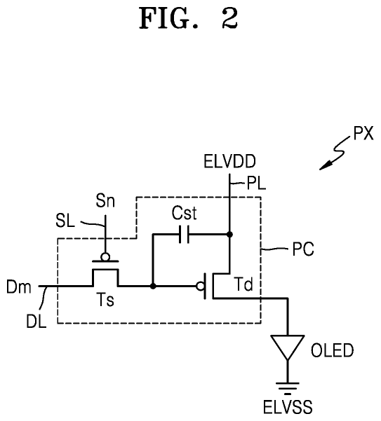

FIG. 2 is a diagram of an equivalent circuit schematically illustrating a pixel included in the display apparatus of FIG. 1.

Referring to FIG. 2, each pixel PX may include a pixel circuit PC connected to the scan line SL and the data line DL, and an organic light-emitting diode OLED connected to the pixel circuit PC. The pixel circuit PC may include a driving thin-film transistor Td, a switching thin-film transistor Ts, and a storage capacitor Cst. The switching thin-film transistor Ts is connected to the scan line SL and the data line DL, and transmits a data signal Dm input through the data line DL to the driving thin-film transistor Td according to a scan signal Sn input through the scan line SL.

The storage capacitor Cst may be connected to the switching thin-film transistor Ts and the driving voltage line PL, and may store a voltage corresponding to a difference between a voltage received from the switching thin-film transistor Ts and a first power supply voltage ELVDD supplied to the driving voltage line PL. The second power supply voltage ELVSS may be a driving voltage having a lower level than the first power supply voltage ELVDD. A level of a driving voltage supplied to each pixel PX may be a difference between levels of the first power supply voltage ELVDD and the second power supply voltage ELVSS.

The driving thin-film transistor Td may be connected to the driving voltage line PL and the storage capacitor Cst, and may control driving current flowing through the organic light-emitting diode OLED from the driving voltage line PL in response to a value of the voltage stored in the storage capacitor Cst. The organic light-emitting diode OLED may emit light having a certain luminance due to the driving current.

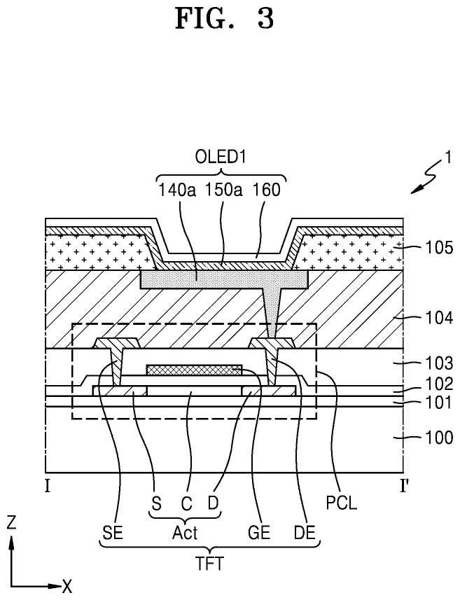

FIG. 3 is a cross-sectional view schematically illustrating a display apparatus, according to an embodiment. In detail, FIG. 3 is a cross-sectional view schematically illustrating the display apparatus of FIG. 1, taken along line I-I′.

Referring to FIG. 3, the display apparatus 1 may include the substrate 100, a pixel circuit layer PCL, and a first organic light-emitting diode OLED1.

For ultra-high resolution, the substrate 100 may include a semiconductor material, for example, a group IV semiconductor, a group III-V compound semiconductor, or a group II-VI compound semiconductor. The substrate 100 may include a silicon layer. For example, the substrate 100 may be a semiconductor substrate including a semiconductor material. In an embodiment, the substrate 100 may be a C-MOS substrate. As such, an OLED display apparatus using the substrate 100 including a semiconductor material may be referred to as an OLED on silicon (OLEDoS). OLEDoS may be used in extended reality (XR), and may have ultra-high definition of 8 K or more in a small area of about 1 to 2 inches. In case that a semiconductor substrate is used, pixels arranged at ultra-high resolution may be closely controlled. In other words, in the case of a micro-display apparatus in which one pixel PX (see FIG. 1) has a length in a range of about 2 μm to about 4 μm in a first direction (e.g., an x direction or a −x direction), a semiconductor substrate may be used. However, the disclosure is not limited thereto.

A type of the substrate 100 is not limited to a semiconductor substrate. For example, the substrate 100 may include glass, a metal, and/or a polymer resin. The substrate 100 may include a polymer resin such as polyethersulfone, polyacrylate, polyetherimide, polyethylene naphthalate, polyethylene terephthalate, polyphenylene sulfide, polyarylate, polyimide, polycarbonate, cellulose acetate propionate, or a combination thereof. However, various modifications may be made. For example, the substrate 100 may have a multi-layer structure including two layers each including a polymer resin and a barrier layer including an inorganic material (e.g., silicon oxide, silicon nitride, or silicon oxynitride) and located between the two layers.

A buffer layer 101 may be located on the substrate 100. The buffer layer 101 may serve as a barrier layer and/or a blocking layer for preventing diffusion of impurity ions, preventing penetration of moisture or external air, and/or planarizing a surface. The buffer layer 101 may include, e.g., silicon oxide, silicon nitride, silicon oxynitride, or a combination thereof. Also, the buffer layer 101 may adjust a heat supply rate during a crystallization process for forming a semiconductor layer Act such that the semiconductor layer Act is uniformly crystalized. However, the disclosure is not limited thereto. In another embodiment, the buffer layer may be omitted.

The pixel circuit layer PCL may be located on the substrate 100 or the buffer layer 101. The pixel circuit layer PCL may include at least one thin-film transistor TFT electrically connected to the first organic light-emitting diode OLED1, a gate insulating layer 102, and an interlayer insulating layer 103. In an embodiment, the thin-film transistor TFT may include the semiconductor layer Act, a gate electrode GE, a source electrode SE, and a drain electrode DE.

In an embodiment, the semiconductor layer Act may be located on the buffer layer 101. The semiconductor layer Act may be formed of various materials, e.g., polysilicon, and may include a channel region C not doped with impurities and a source region S and a drain region D formed by doping impurities on both sides of the channel region C. The impurities may vary according to a type of the thin-film transistor TFT, and may be N-type impurities or P-type impurities.

In an embodiment, the gate insulating layer 102 may be located on the semiconductor layer Act. The gate insulating layer 102 may be an element for ensuring insulation between the semiconductor layer Act and the gate electrode GE. The gate insulating layer 102 may include an inorganic material such as silicon oxide, silicon nitride, and/or silicon oxynitride, and may be located between the semiconductor layer Act and the gate electrode GE. Also, the gate insulating layer 102 may be formed to correspond to an entire surface of the substrate 100, and may have a structure in which contact holes are formed in pre-set portions. As such, an insulating film including an inorganic material may be formed by using chemical vapor deposition (CVD) or atomic layer deposition (ALD). This may apply to the following embodiments and modifications thereof.

The gate electrode GE may be located on the gate insulating layer 102. The gate electrode GE may vertically overlap the semiconductor layer Act, and may include, e.g., at least one metal from among molybdenum (Mo), aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), titanium (Ti), tungsten (W), and copper (W).

The interlayer insulating layer 103 may be located on the gate electrode GE. The interlayer insulating layer 103 may cover (or overlap) the gate electrode GE. The interlayer insulating layer 103 may be formed of, e.g., an inorganic material. For example, the interlayer insulating layer 103 may be formed of a metal oxide or a metal nitride. For example, the inorganic material may include silicon oxide (SiO₂), silicon nitride (SiNx), silicon oxynitride (SiON), aluminum oxide (Al₂O₃), titanium oxide (TiO₂), tantalum oxide (Ta₂O₅), hafnium oxide (HfO₂), zinc oxide (ZrO₂), or a combination thereof. The interlayer insulating layer 103 may have a single-layer structure or a double-layer structure formed of SiOₓ/SiN_{y} or SiNₓ/SiO_{y} in some embodiments.

Each of the source electrode SE and the drain electrode DE may be located on the interlayer insulating layer 103. The source electrode SE and the drain electrode DE may be respectively electrically connected to the source region S and the drain region D of the semiconductor layer Act through through-holes included in the interlayer insulating layer 103. Each of the source electrode SE and the drain electrode DE may include, e.g., at least one metal selected from among aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu). For example, each of the source electrode SE and the drain electrode DE may include a Ti layer, an Al layer, and/or a Cu layer.

The semiconductor layer Act, the gate electrode GE, the source electrode SE, and the drain electrode DE may form at least one of the thin-film transistors described with reference to FIG. 2. According to a pattern of a pre-selected shape, the semiconductor layer Act, the gate electrode GE, the source electrode SE, and the drain electrode DE may constitute at least one of the thin-film transistors described with reference to FIG. 2.

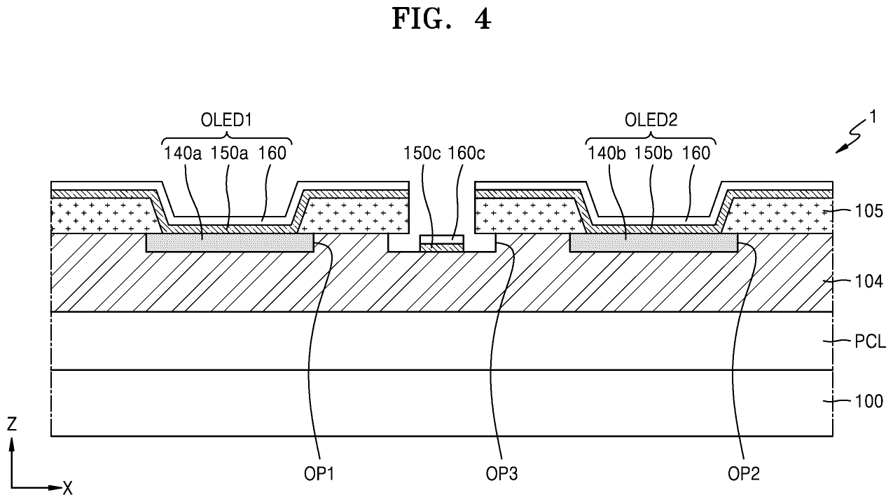

An organic insulating layer 104 may be located on the source electrode SE and the drain electrode DE. The organic insulating layer 104 may be an organic insulating layer functioning as a planarization film covering the source electrode SE and the drain electrode DE and having a substantially flat top surface. The organic insulating layer 104 may include, for example, an organic material such as acryl, benzocyclobutene (BCB), or hexamethyldisiloxane (HMDSO). Various modifications may be made. For example, the organic insulating layer 104 may have a single or multi-layer structure. The organic insulating layer may include an opening, which will be described in more detail with reference to FIG. 4.

Although not shown in FIG. 3, an additional electrode and additional insulating layers may be located between the source electrode SE and drain electrode DE and the pixel electrode 140, and may be applied to various embodiments. In this case, the additional electrode, and the source electrode SE and the drain electrode DE may include the same material and may have the same layer structure. The additional insulating layer and the organic insulating layer 104 may include the same material and have the same layer structure.

In an embodiment, the first organic light-emitting diode OLED1 electrically connected to the pixel circuit layer PCL may be located on the pixel circuit layer PCL. The first organic light-emitting diode OLED1 may include a first pixel electrode 140a, a first intermediate layer 150a, and a counter electrode 160.

The first pixel electrode 140a may be located on the pixel circuit layer PCL. The first pixel electrode 140a may be located in an opening of the organic insulating layer 104. The first pixel electrode 140a may be connected to the source electrode or the drain electrode through a contact hole formed in the organic insulating layer 104.

The first pixel electrode 140a may be formed as a (semi-)transparent electrode or a reflective electrode. In case that the first pixel electrode 140a is formed as a (semi-)transparent electrode, the first pixel electrode 140a may be formed of, e.g., indium tin oxide (ITO), indium zinc oxide (IZO), zinc oxide (ZnO), indium oxide (In₂O₃), indium gallium oxide (IGO), aluminum zinc oxide (AZO), or a combination thereof. In case that the first pixel electrode 140a is formed as a reflective electrode, a reflective film formed of, e.g., Ag, Mg, Al, Pt, Pd, Au, Ni, Nd, Ir, Cr, or a combination thereof may be formed, and a film formed of, e.g., ITO, IZO, ZnO, or In₂O₃ may be formed on the reflective film. In an embodiment, the first pixel electrode 140a may have a structure in which an ITO layer, a silver (Ag) layer, and an ITO layer are sequentially stacked.

A pixel-defining film 105 including an opening through which at least a part of the first pixel electrode 140a is exposed may be located on the first pixel electrode 140a. An emission area of light emitted from the first organic light-emitting diode OLED1 may be defined by the opening defined in the pixel-defining film 105. For example, a width of the opening may correspond to a width of the emission area.

The pixel-defining film 105 may include various materials, e.g., an organic insulating material. As another example, the pixel-defining film 105 may include an inorganic insulating material such as silicon nitride, silicon oxynitride, or silicon oxide. As yet another example, the pixel-defining film 105 may include an organic insulating material and an inorganic insulating material. In an embodiment, the pixel-defining film 105 may include a light-blocking material. The light-blocking material may include, e.g., carbon black, carbon nanotubes, a resin or paste including a black dye, metal particles such as nickel, aluminum, molybdenum, or an alloy thereof, metal oxide particles (e.g., chromium oxide), or metal nitride particles (e.g., chromium nitride). In case that the pixel-defining film 105 includes a light-blocking material, the reflection of external light due to metal structures located under the pixel-defining film 105 may be reduced.

The first intermediate layer 150a may be located in the opening of the pixel-defining film 105. The first intermediate layer 150a may include a high molecular weight or low molecular weight organic material emitting light of a certain color.

Although not shown, a first functional layer and a second functional layer may be located under and over the first intermediate layer 150a. The first functional layer and the second functional layer may be continuously located on the substrate 100. The first functional layer may be located between the first pixel electrode 140a and the first intermediate layer 150a, and the second functional layer may be located between the first intermediate layer 150a and the counter electrode 160. However, at least one of the first functional layer and the second functional layer may be omitted. Embodiments will be described below in detail assuming that both the first functional layer and the second functional layer are located.

The first functional layer may include a hole transport layer (HTL) and/or a hole injection layer (HIL). The second functional layer may include an electron transport layer (ETL) and/or an electron injection layer (EIL). The first functional layer and/or the second functional layer may be a common layer entirely covering the substrate 100, similar to the counter electrode 160 described below.

In an embodiment, the counter electrode 160 may be located on the first intermediate layer 150a. The counter electrode 160 may be formed of a conductive material having a low work function. For example, the counter electrode 160 may include a (semi-)transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or an alloy thereof. As another example, the counter electrode 160 may further include a layer such as ITO, IZO, ZnO, or In₂O₃ on the (semi-)transparent layer including the above material.

Although not shown, in an embodiment, an encapsulation layer may be located on the first organic light-emitting diode OLED1. The encapsulation layer may cover the first organic light-emitting diode OLED1. The encapsulation layer may be located on the counter electrode 160. In an embodiment, the encapsulation layer may include at least one inorganic layer and at least one organic layer. The encapsulation layer includes a first inorganic layer, an organic layer, and a second inorganic layer which are sequentially stacked.

Each of the first inorganic layer and the second inorganic layer may include, e.g., at least one inorganic material from among aluminum oxide, titanium oxide, tantalum oxide, hafnium oxide, zinc oxide, silicon oxide, silicon nitride, silicon oxynitride, or a combination thereof. Each of the first inorganic layer and the second inorganic layer may have a single or multi-layer structure including the above material. The organic layer may include a polymer-based material. Examples of the polymer-based material may include an acrylic resin, an epoxy resin, polyimide, and polyethylene. In an embodiment, the organic layer may include acrylate.

FIG. 4 is a cross-sectional view schematically illustrating a display apparatus. In detail, FIG. 4 is a cross-sectional view illustrating a first organic light-emitting diode and a second organic light-emitting diode of a display apparatus.

Referring to FIG. 3, as described above, the pixel circuit layer PCL may be located on the substrate 100, and the organic insulating layer 104 may be located on the pixel circuit layer PCL. The first organic light-emitting diode OLED1 and a second organic light-emitting diode OLED2 may be located on the organic insulating layer 104. The first organic light-emitting diode OLED1 may include the first pixel electrode 140a, the first intermediate layer 150a, and the counter electrode 160, and the second organic light-emitting diode OLED2 may include a second pixel electrode 140b, a second intermediate layer 150b, and the counter electrode 160.

In an embodiment, the organic insulating layer 104 may include a first opening OP1, a second opening OP2, and a third opening OP3. The third opening OP3 may be located between the first opening OP1 and the second opening OP2. The first pixel electrode 140a of the first organic light-emitting diode OLED1 may be located in the first opening OP1 of the organic insulating layer 104. In other words, the first pixel electrode 140a of the first organic light-emitting diode OLED1 may be disposed in the first opening OP1 of the organic insulating layer 104. The second pixel electrode 140b of the second organic light-emitting diode OLED2 may be located in the second opening OP2 of the organic insulating layer 104. In other words, the second pixel electrode 140b of the second organic light-emitting diode OLED2 may be disposed in the second opening OP2 of the organic insulating layer 104. Due to a chemical mechanical polishing (CMP) planarization process during a process of manufacturing the display apparatus 1, a top surface of the first pixel electrode 140a and a top surface of the organic insulating layer 104 may be located on the same plane. Due to a CMP planarization process during a process of manufacturing the display apparatus 1, a top surface of the second pixel electrode 140b and a top surface of the organic insulating layer 104 may be located on the same plane.

The pixel-defining film 105 may be located on the first pixel electrode 140a and the second pixel electrode 140b. The pixel-defining film 105 may include openings overlapping at least parts of the first opening OP1 and the second opening OP2. Also, the pixel-defining film 105 may include an opening overlapping at least a part of the third opening OP3 of the organic insulating layer 104. A length of the opening of the pixel-defining film 105 overlapping at least a part of the third opening OP3 in the first direction (e.g., the x direction or the −x direction) may be less than a length of the third opening OP3 in the first direction (e.g., the x direction or the −x direction). The pixel-defining film 105 may protrude toward the third opening OP3 beyond the organic insulating layer 104 in the third opening OP3 of the organic insulating layer 104. In other words, the pixel-defining film 105 may be provided in an undercut shape in the third opening OP3 of the organic insulating layer 104.

The first intermediate layer 150a, the second intermediate layer 150b, a dummy intermediate layer 150c, and the counter electrode 160 may be located on the pixel-defining film 105. The first intermediate layer 150a may overlap the first pixel electrode 140a. The second intermediate layer 150b may overlap the second pixel electrode 140b. The dummy intermediate layer 150c may be located in the third opening OP3 of the organic insulating layer 104. The counter electrode 160 may be continuously located on the substrate 100. The first organic light-emitting diode OLED1 may include the first pixel electrode 140a, the first intermediate layer 150a, and the counter electrode 160, and the second organic light-emitting diode OLED2 may include the second pixel electrode 140b, the second intermediate layer 150b, and the counter electrode 160.

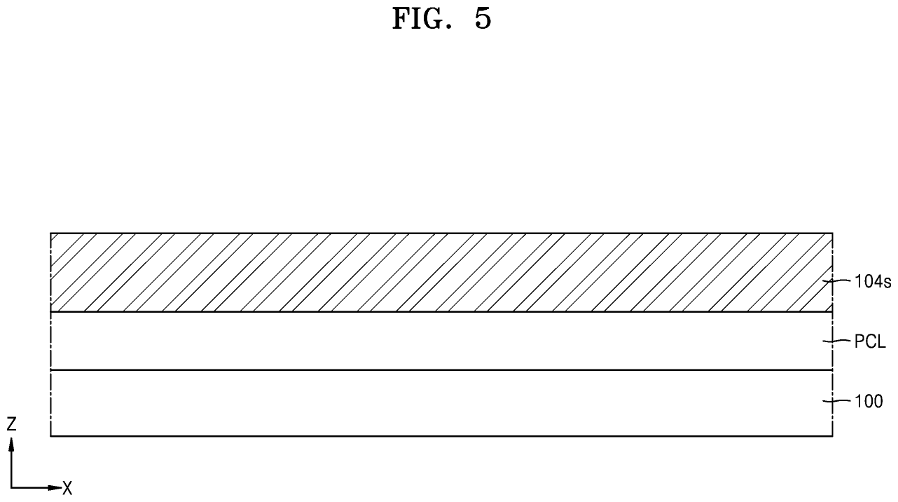

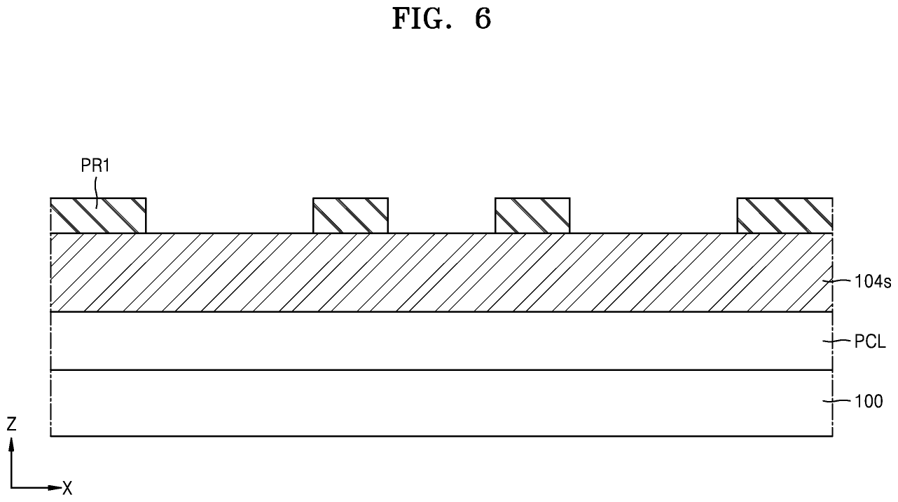

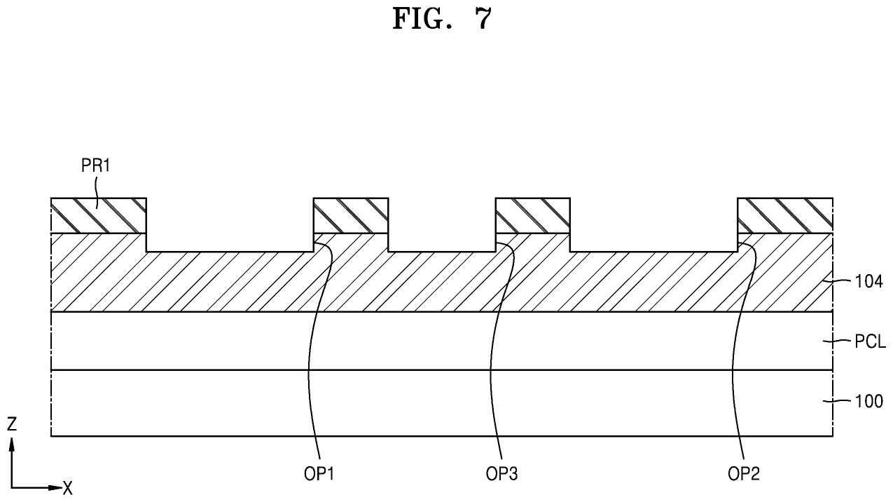

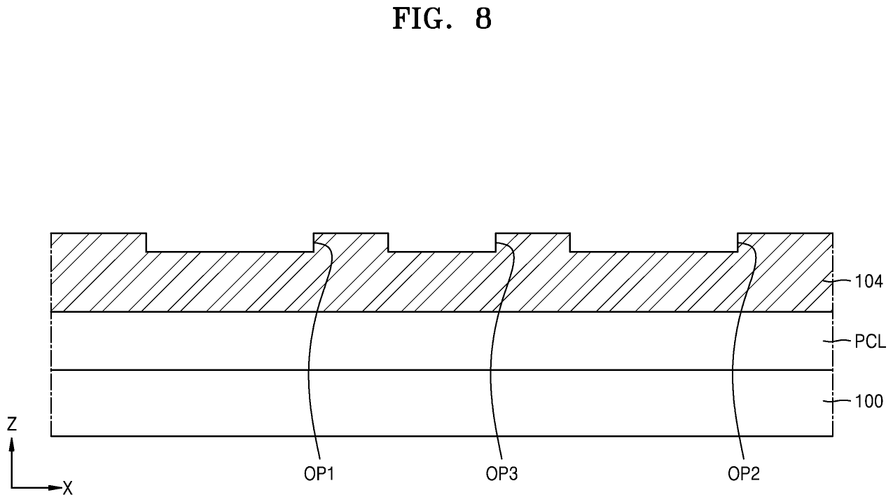

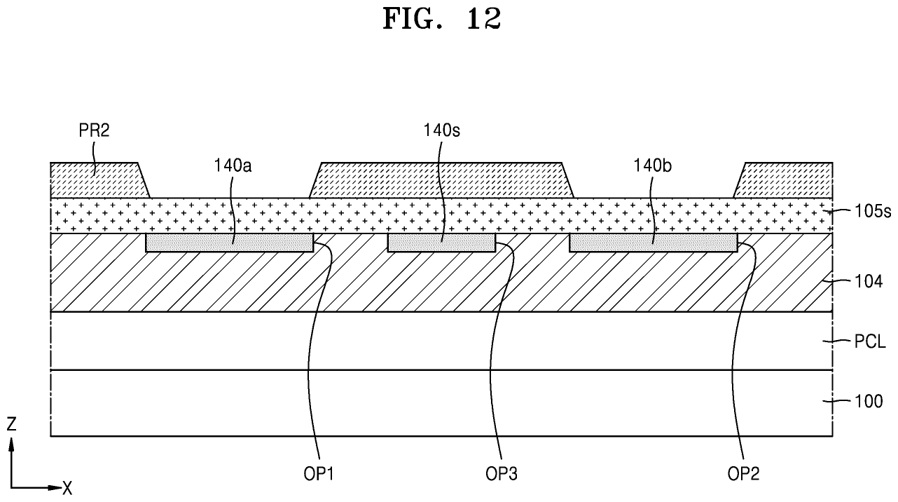

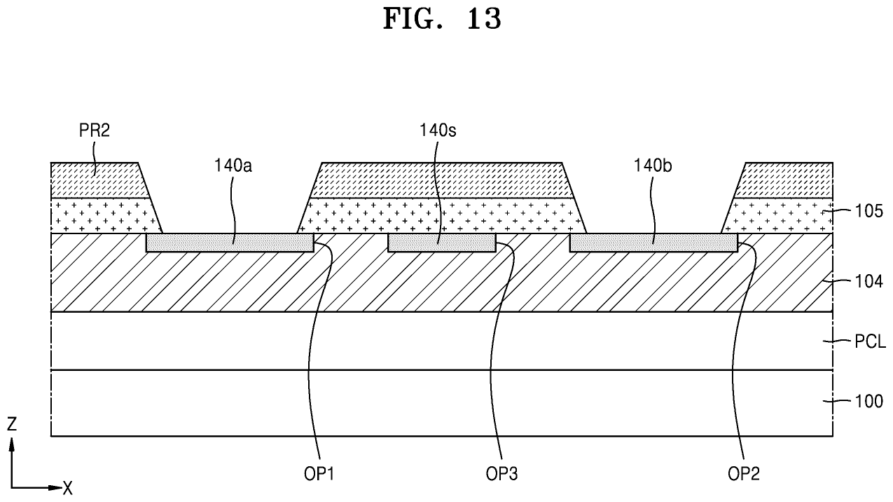

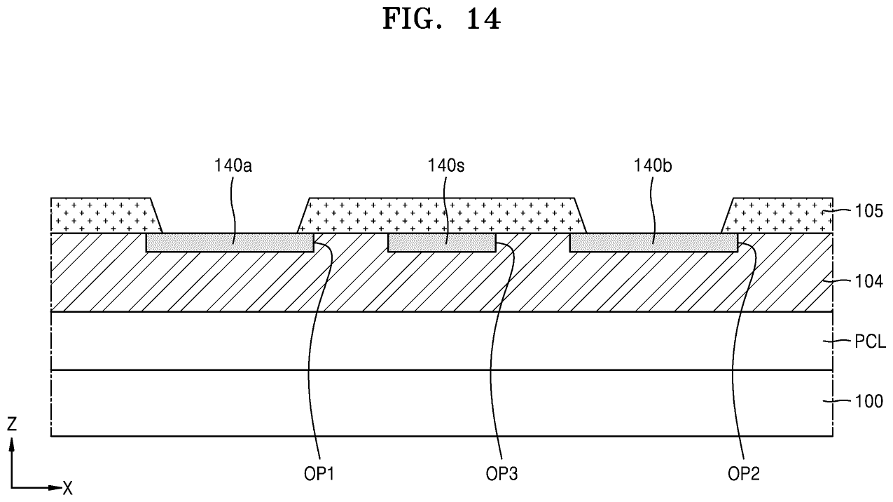

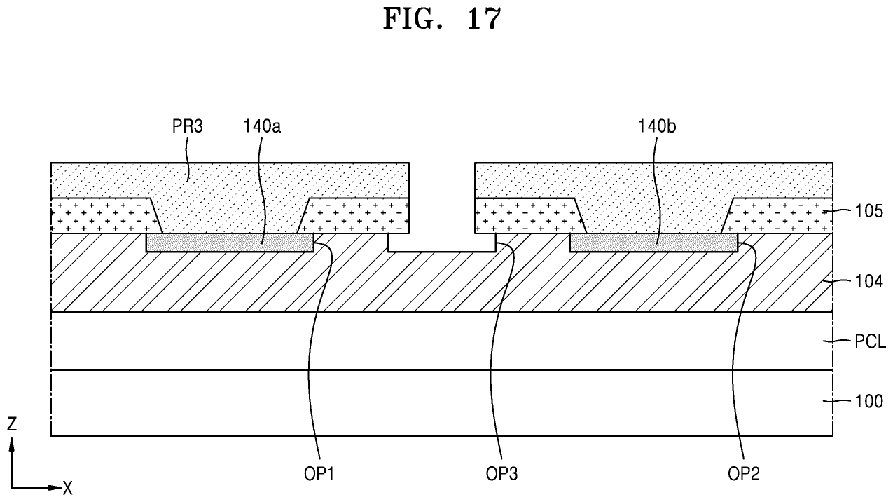

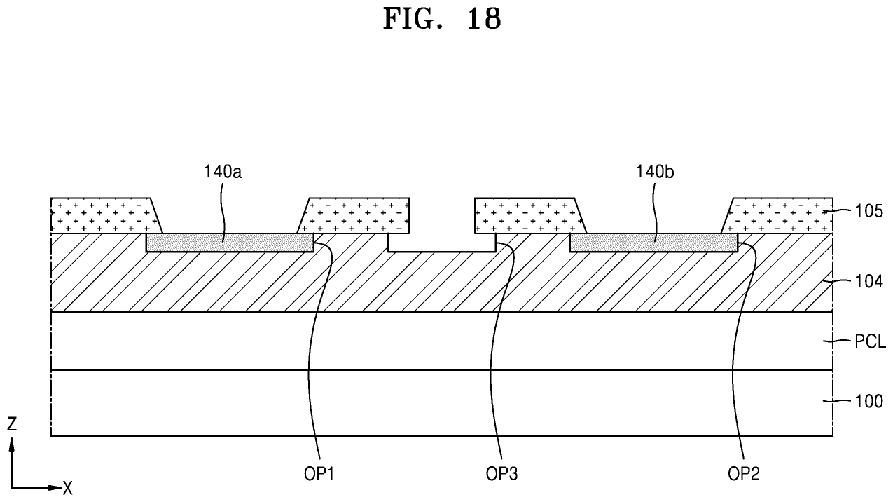

FIGS. 5 to 19 are cross-sectional views schematically illustrating a method of manufacturing a display apparatus.

Referring to FIGS. 5 to 19, a method of manufacturing the display apparatus 1 may include forming the organic insulating layer 104 including the first opening OP1, the second opening OP2, and the third opening OP3 on the substrate 100, respectively forming the first pixel electrode 140a and the second pixel electrode 140b in the first opening OP1 and the second opening OP2 of the organic insulating layer 104, forming, on the organic insulating layer 104, the pixel-defining film 105 protruding toward the third opening OP3 beyond the organic insulating layer 104, respectively forming the first intermediate layer 150a and the second intermediate layer 150b on the first pixel electrode 140a and the second pixel electrode 140b, and locating the counter electrode 160 on the first intermediate layer 150a and the second intermediate layer 150b.

Referring to FIGS. 5 to 8, the organic insulating layer 104 including the first opening OP1, the second opening OP2, and the third opening OP3 may be formed on the substrate 100. The pixel circuit layer PCL may be located on the substrate 100, and an organic insulating layer forming material 104s may be located on the pixel circuit layer PCL. The organic insulating layer forming material 104s may include, for example, an organic material such as acryl, benzocyclobutene (BCB), or hexamethyldisiloxane (HMDSO). Various modifications may be made. For example, the organic insulating layer forming material 104s may have a single or multi-layer structure.

A first photoresist PR1 may be located on at least a part of the organic insulating layer forming material 104s. A portion of the organic insulating layer forming material 104s on which the first photoresist PR1 is not located may be etched. For example, a portion of the organic insulating layer forming material 104s on which the first photoresist PR1 is not located may be dry etched. At least a part of the organic insulating layer forming material 104s may be etched, to form the organic insulating layer 104 including the first opening OP1, the second opening OP2, and the third opening OP3. The third opening OP3 of the organic insulating layer 104 may be located between the first opening OP1 and the second opening OP2. Next, the first photoresist PR1 may be removed.

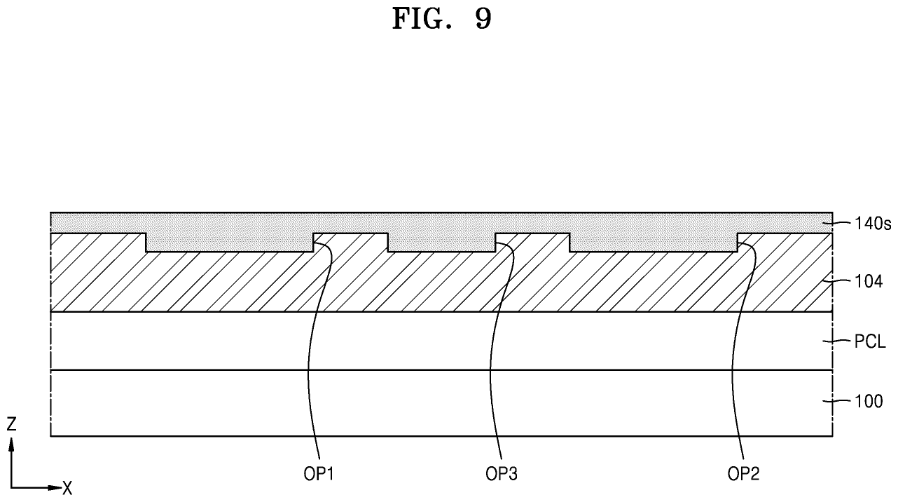

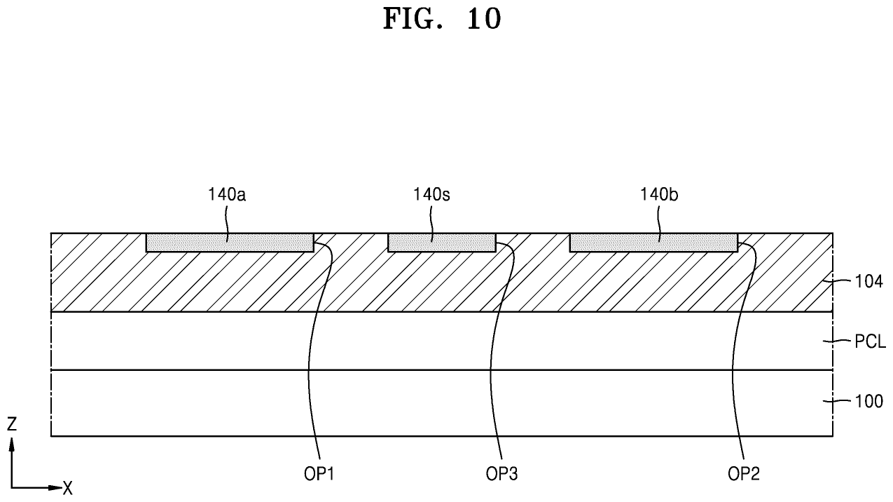

Referring to FIGS. 9 and 10, the first pixel electrode 140a and the second pixel electrode 140b may be respectively formed in the first opening OP1 and the second opening OP2 of the organic insulating layer 104. A pixel electrode forming material 140s may be located on the substrate 100. The pixel electrode forming material 140s may be located on a top surface of the organic insulating layer 104. The pixel electrode forming material 140s may be located in the first opening OP1, the second opening OP2, and the third opening OP3 of the organic insulating layer 104.

The pixel electrode forming material 140s may be formed to be a (semi-)transparent electrode or may be formed to be a reflective electrode. In case that the pixel electrode forming material 1470s is formed to be a (semi-)transparent electrode, the pixel electrode forming material 140s may be formed of, e.g., ITO, IZO, ZnO, In₂O₃, IGO, AZO, or a combination thereof. In case that the pixel electrode forming material 140s is formed to be a reflective electrode, a reflective film formed of, e.g., Ag, Mg, Al, Pt, Pd, Au, Ni, Nd, Ir, Cr, or a combination thereof may be formed and a film formed of, e.g., ITO, IZO, ZnO, In₂O₃, or a combination thereof may be formed on the reflective film. In an embodiment, the pixel electrode forming material 140s may have a structure in which an ITO layer, an Ag layer, and an ITO layer are sequentially stacked.

In an embodiment, the display apparatus 1 may be the display apparatus 1 including a micro-organic light-emitting diode (micro-OLED). The display apparatus 1 including the micro-OLED may include a semiconductor substrate, and the display apparatus 1 including the semiconductor substrate may use a chemical mechanical polishing (CMP) process. The organic insulating layer 104 and the pixel electrode forming material 140s located on the substrate 100 may be planarized through a CMP process such that a top surface of the organic insulating layer 104 and a top surface of the pixel electrode forming material 140s are located on the same plane.

The pixel electrode forming material 140s located in the first opening OP1 of the organic insulating layer 104 may be the first pixel electrode 140a. The pixel electrode forming material 140s located in the second opening OP2 of the organic insulating layer 104 may be the second pixel electrode 140b. The pixel electrode forming material 140s may be located in the third opening OP3 of the organic insulating layer 104.

Through a CMP process, a top surface of the first pixel electrode 140a and a top surface of the organic insulating layer 104 may be located on the same plane. Through a CMP process, a top surface of the second pixel electrode 140b and a top surface of the organic insulating layer 104 may be located on the same plane.

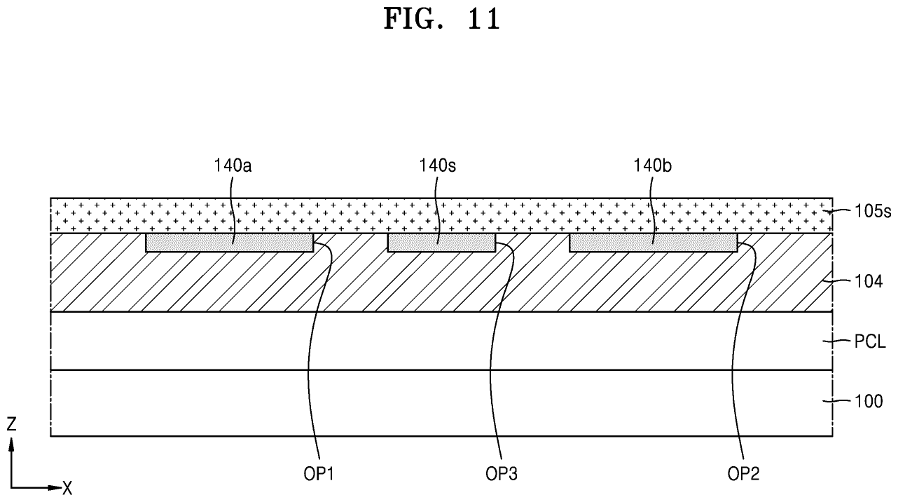

Referring to FIGS. 11 to 14, the pixel-defining film 105 protruding toward the third opening OP3 beyond the organic insulating layer 104 may be formed on the organic insulating layer 104. A pixel-defining film forming material 105s may be located on the substrate 100. The pixel-defining film forming material 105s may include an organic insulating material. As another example, the pixel-defining film forming material 105s may include an inorganic insulating material such as silicon nitride, silicon oxynitride, or silicon oxide. As yet another example, the pixel-defining film forming material 105s may include an organic insulating material and an inorganic insulating material. In an embodiment, the pixel-defining film forming material 105s may include a light-blocking material. The light-blocking material may include carbon black, carbon nanotubes, a resin or paste including a black dye, metal particles such as nickel, aluminum, molybdenum, or an alloy thereof, metal oxide particles (e.g., chromium oxide), or metal nitride particles (e.g., chromium nitride). In case that the pixel-defining film forming material 105s includes a light-blocking material, the reflection of external light due to metal structures located under the pixel-defining film forming material 105s may be reduced.

A second photoresist PR2 may be located on at least a part of the pixel-defining film forming material 105s. A portion of the pixel-defining film forming material 105s on which the second photoresist PR2 is not located may be etched. For example, a portion of the pixel-defining film forming material 105s on which the second photoresist PR2 is not located may be dry etched. At least a part of the pixel-defining film forming material 105s may be etched, to form the pixel-defining film 105 including openings overlapping at least parts of the first opening OP1 and the second opening OP2 of the organic insulating layer 104. Next, the second photoresist PR2 may be removed.

The pixel-defining film 105 may expose at least a part of the first pixel electrode 140a through an opening overlapping at least a part of the first opening OP1 of the organic insulating layer 104. The pixel-defining film 105 may expose at least a part of the second pixel electrode 140b through an opening overlapping at least a part of the second opening OP2 of the organic insulating layer 104.

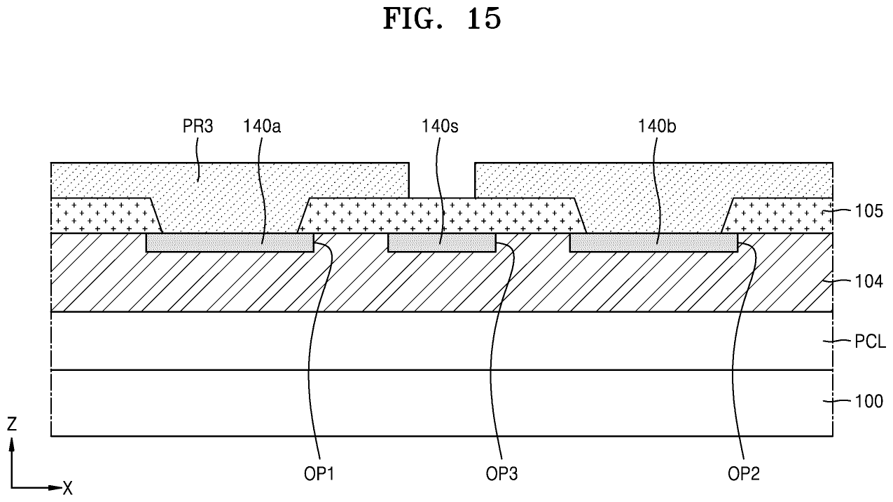

Referring to FIGS. 15 to 18, an opening overlapping at least a part of the third opening OP3 may be formed in the pixel-defining film 105, and the pixel electrode forming material 140s located in the third opening OP3 of the organic insulating layer 104 may be removed.

A third photoresist PR3 may be located on at least a part of the pixel-defining film 105. A portion of the pixel-defining film 105 on which the third photoresist PR3 is not located may be etched. For example, a portion of the pixel-defining film 105 on which the third photoresistor PR3 is not located may be dry etched. At least a part of the pixel-defining film 105 may be etched, to form an opening overlapping at least a part of the third opening OP3 of the organic insulating layer in the pixel-defining film 105. At least a part of the pixel electrode forming material 140s located in the third opening OP3 of the organic insulating layer 104 may be exposed, through the opening of the pixel-defining film 105 overlapping at least a part of the third opening OP3 of the organic insulating layer 104.

The pixel electrode forming material 140s located in the third opening OP3 of the organic insulating layer 104 may be etched and removed. For example, the pixel electrode forming material 140s located in the third opening OP3 of the organic insulating layer 104 may be removed through wet etching. Next, the third photoresist PR3 may be removed.

At least a part of the pixel-defining film 105 may be etched to form an opening overlapping at least a part of the third opening OP3, and the pixel electrode forming material 140s located in the third opening OP3 may be removed to provide the pixel-defining film 105 in an undercut shape in the third opening OP3. The pixel-defining film 105 may protrude toward the third opening OP3 beyond the organic insulating layer 104. A size of the opening of the pixel-defining film 105 overlapping at least a part of the third opening OP3 in the first direction (e.g., the x direction or the −x direction) may be less than a size of the third opening OP3 in the first direction (e.g., the x direction or the −x direction).

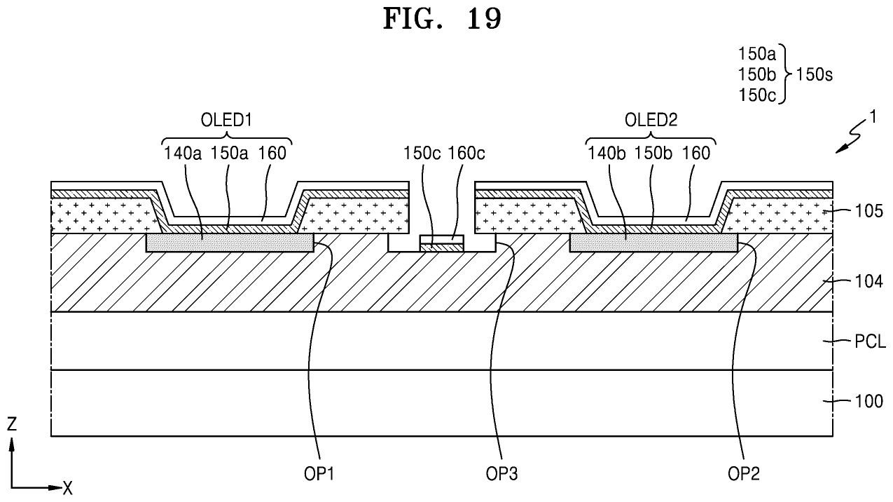

Referring to FIG. 19, the first intermediate layer 150a, the second intermediate layer 150b, the dummy intermediate layer 150c, and the counter electrode 160 may be formed on the substrate 100. An intermediate layer forming material 150s may be continuously located on the substrate 100. The intermediate layer forming material 150s may include a high molecular weight or low molecular weight organic material emitting light of a certain color.

The intermediate layer forming material 150s may be separated in the third opening OP3 of the organic insulating layer 104. For example, the intermediate layer forming material 150s may be separated in the third opening OP3, due to the undercut shape of the pixel-defining film 105 located in the third opening OP3. The intermediate layer forming material 150s separated in the third opening OP3 and located in the third opening OP3 may form the dummy intermediate layer 150c. The intermediate layer forming material 150s overlapping the first pixel electrode 140a may form the first intermediate layer 150a. The intermediate layer forming material 150s overlapping the second pixel electrode 140b may form the second intermediate layer 150b.

In a conventional method, a separator was formed by stacking multiple layers and patterning the layers, and an intermediate layer forming material may be separated due to the separator located between organic light-emitting diodes OLED. As the intermediate layer forming material is separated by the separator, lateral leakage current of the display apparatus may be reduced, thereby improving the resolution of the display apparatus.

In an embodiment, the display apparatus 1 may be the display apparatus 1 including a micro-OLED. In the display apparatus 1 including the micro-OLED, a distance between any micro-OLED and another adjacent micro-OLED may be in a range of about 0.5 μm to about 2 μm. Because a distance between the micro-OLEDs is short, it may be inappropriate to locate a separator, which is formed by stacking multiple layers and patterning the layers to separate the intermediate layer forming material 150s, between the micro-OLEDs.

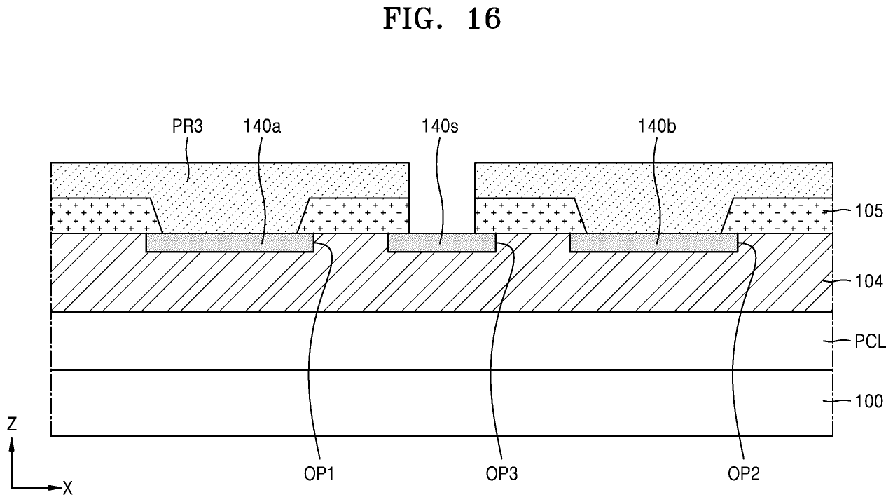

The display apparatus 1 including the micro-OLED may include a semiconductor substrate. The display apparatus 1 including the semiconductor substrate may use a CMP process during a manufacturing process. Through the CMP process, a top surface of the first pixel electrode 140a, a top surface of the second pixel electrode 140b, and a top surface of the organic insulating layer 104 may be located on the same plane. Next, an opening overlapping at least a part of the third opening OP3 of the organic insulating layer 104 may be formed in the pixel-defining film 105, and the pixel electrode forming material 140s (see FIG. 16) located in the third opening OP3 may be removed, to provide the pixel-defining film 105 in an undercut shape in the third opening OP3. Because the pixel-defining film 105 is provided in an undercut shape in the third opening OP3 of the organic insulating layer 104, the intermediate layer forming material 150s may be separated in the third opening OP3, and lateral leakage current of the display apparatus 1 may be reduced, thereby improving the resolution of the display apparatus 1.

The counter electrode 160 may be continuously formed on the substrate 100. Even the counter electrode 160 may also be separated in the third opening OP3, due to the undercut structure of the pixel-defining film 105 formed in the third opening OP3. The counter electrode 160 separated in the third opening OP3 and located in the third opening OP3 may be a dummy counter electrode 160c. The first organic light-emitting diode OLED1 may include the first pixel electrode 140a, the first intermediate layer 150a, and the counter electrode 160, and the second organic light-emitting diode OLED2 may include the second pixel electrode 140b, the second intermediate layer 150b, and the counter electrode 160.

In a conventional method, a separator was formed by stacking multiple layers and patterning the layers, and an intermediate layer forming material may be separated due to the separator located between organic light-emitting diodes OLED. As the intermediate layer forming material is separated by the separator, lateral leakage current of the display apparatus may be reduced, thereby improving the resolution of the display apparatus.

In an embodiment, the display apparatus 1 including the micro-OLED may include a semiconductor substrate. The display apparatus 1 including the semiconductor substrate may use a CMP process during a manufacturing process. Through the CMP process, a top surface of the first pixel electrode 140a, a top surface of the second pixel electrode 140b, and a top surface of the organic insulating layer 104 may be located on the same plane. Next, an opening overlapping at least a part of the third opening OP3 of the organic insulating layer 104 may be formed in the pixel-defining film 105, and the pixel electrode forming material 140s located in the third opening OP3 may be removed, to provide the pixel-defining film 105 in an undercut shape in the third opening OP3. Because the pixel-defining film 105 is provided in an undercut shape in the third opening OP3 of the organic insulating layer 104, the intermediate layer forming material 150s may be separated in the third opening OP3, and lateral leakage current of the display apparatus 1 may be reduced, thereby improving the resolution of the display apparatus 1.

According to embodiments, a display apparatus having improved reliability and resolution and a method of manufacturing the display apparatus may be provided. However, the scope of the disclosure is not limited by this effect.

The above description is an example of technical features of the disclosure, and those skilled in the art to which the disclosure pertains will be able to make various modifications and variations. Thus, the embodiments of the disclosure described above may be implemented separately or in combination with each other.

The embodiments disclosed in the disclosure are intended not to limit the technical spirit of the disclosure but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display apparatus comprising:
an organic insulating layer located on a substrate, and comprising a first opening, a second opening, and a third opening;
a first pixel electrode and a second pixel electrode each located on the organic insulating layer and respectively disposed in the first opening and the second opening;
a pixel-defining film located on the organic insulating layer and protruding toward the third opening beyond the organic insulating layer;
a first intermediate layer and a second intermediate layer respectively located on the first pixel electrode and the second pixel electrode; and
a counter electrode located on the first intermediate layer and the second intermediate layer.

2. The display apparatus of claim 1, wherein the pixel-defining film has an undercut shape in the third opening of the organic insulating layer.

3. The display apparatus of claim 1, wherein the pixel-defining film comprises openings overlapping at least parts of the first opening, the second opening, and the third opening.

4. The display apparatus of claim 1, wherein the third opening of the organic insulating layer is located between the first opening and the second opening.

5. The display apparatus of claim 1, further comprising:
a dummy intermediate layer located in the third opening of the organic insulating layer.

6. The display apparatus of claim 1, wherein a first organic light-emitting diode comprises the first pixel electrode, the first intermediate layer, and the counter electrode.

7. The display apparatus of claim 1, wherein a second organic light-emitting diode comprises the second pixel electrode, the second intermediate layer, and the counter electrode.

8. The display apparatus of claim 1, wherein a top surface of the first pixel electrode and a top surface of the organic insulating layer are located on a same plane.

9. The display apparatus of claim 1, wherein a top surface of the second pixel electrode and a top surface of the organic insulating layer are located on a same plane.

10. A method of manufacturing a display apparatus, the method comprising:
forming, on a substrate, an organic insulating layer comprising a first opening, a second opening, and a third opening;
respectively forming a first pixel electrode and a second pixel electrode in the first opening and the second opening of the organic insulating layer;
forming, on the organic insulating layer, a pixel-defining film protruding toward the third opening beyond the organic insulating layer;
respectively forming a first intermediate layer and a second intermediate layer on the first pixel electrode and the second pixel electrode; and
locating a counter electrode on the first intermediate layer and the second intermediate layer.

11. The method of claim 10, wherein the pixel-defining film is provided in an undercut shape in the third opening of the organic insulating layer.

12. The method of claim 10, wherein the pixel-defining film comprises openings overlapping at least parts of the first opening, the second opening, and the third opening of the organic insulating layer.

13. The method of claim 10, further comprising:
forming a dummy intermediate layer in the third opening of the organic insulating layer.

14. The method of claim 10, wherein
a first organic light-emitting diode comprises the first pixel electrode, the first intermediate layer, and the counter electrode, and
a second organic light-emitting diode comprises the second pixel electrode, the second intermediate layer, and the counter electrode.

15. The method of claim 10, further comprising:
locating an organic insulating layer forming material on the substrate;
locating a first photoresist on at least a part of the organic insulating layer forming material;
forming the organic insulating layer comprising the first opening, the second opening, and the third opening, by etching a portion of the organic insulating layer forming material on which the first photoresist is not located; and
removing the first photoresist.

16. The method of claim 12, further comprising:
locating a pixel electrode forming material on the organic insulating layer; and
forming the first pixel electrode and the second pixel electrode, by planarizing the pixel electrode forming material such that a top surface of the pixel electrode forming material and a top surface of the organic insulating layer are located on a same plane.

17. The method of claim 12, further comprising:
locating a pixel-defining film forming material on the organic insulating layer;
locating a second photoresist on at least a part of the pixel-defining film forming material;
forming the pixel-defining film comprising the openings overlapping at least parts of the first opening and the second opening, by etching a portion of the pixel-defining film forming material on which the second photoresist is not located; and
removing the second photoresist.

18. The method of claim 16, further comprising:
locating a third photoresist on at least a part of the pixel-defining film; and
forming an opening overlapping at least a part of the third opening in the pixel-defining film by etching a portion of the pixel-defining film on which the third photoresist is not located.

19. The method of claim 18, further comprising etching and removing the pixel electrode forming material located in the third opening of the organic insulating layer.

20. The method of claim 13, further comprising:
forming, by locating an intermediate layer forming material on the substrate, the first intermediate layer located on the first pixel electrode, the second intermediate layer located on the second pixel electrode, and the dummy intermediate layer located in the third opening.
